(19) United States
(12) Patent Application Publication
(10) Pub. No.: US 2006/0278879 A1
(43) Pub. Date: Dec. 14, 2006

(54) Nanochannel device and method of manufacturing same

(75) Inventor: Heinz H. Busta, Park Ridge, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(73) Assignee: Cabot Microelectronics Corporation, Aurora, IL (US)

(21) Appl. No.: 11/149,020

(22) Filed: Jun. 9, 2005

(51) Int. Cl. G03F 7/26

(52) U.S. Cl. 257/77; 430/311; 430/313

(57) ABSTRACT

The invention provides a device comprising a substrate, a first material disposed on the substrate to form a first material layer, a second material disposed on the substrate to form a second material layer, and a nanochannel bounded by the substrate, the first material layer, and the second material layer. The invention further provides a method for manufacturing the aforementioned nanoscale device.

### FIELD OF THE INVENTION

This invention pertains to a nanochannel device and method of manufacturing a nanochannel device using step lithography and chemical-mechanical polishing.

### BACKGROUND OF THE INVENTION

Current methods of fabricating nanoscale devices, such as nanofluidic devices, require efficient high resolution lithography. Various optical or electron beam writing approaches have been developed where a small, focused electron or electromagnetic beam is scanned over the surface of a photo resist material, affecting a chemical change in the photo resist material so that it can be removed by subsequent chemical processes. Alternatively, the photo resist material may remain in place after subsequent chemical processing. These approaches have feature size limitations and cost problems.

Optical lithography using projection or direct printing of a mask pattern has been the standard technology for fabricating nanoscale devices. The size of the components produced depends on the ability of the optics to produce very small images on the photo resist material. The size of the components is ultimately limited by the wavelength of the electron or electromagnetic beam used for exposure. In addition, this method only produces a pattern and not a device.

Ultraviolet (UV) lithography is a technique used in large scale production of devices. However, the wavelength of ultraviolet light represents a physical limit to the resolution that can be achieved using this technique.

Conventional electron-beam lithography with single-line writing is inherently slow and costly. Projection electron-beam lithography, sometimes called SCALPEL, can expose about 1 cm² in an exposure time of less than one second, but it is too slow for manufacturing. Projection e-beam lithography also requires special stencil masks and has a relatively poor resolution of several tens of nanometers.

In X-ray lithography, regions of the photo resist material placed between the X-ray source and the sample are covered by a layer of heavy atoms, such as Ta, W, or tantalum silicides, which absorb the X-rays. Such photo resists are fabricated using electron-beam lithography. A major challenge in the fabrication of these photo resists is to use electron-beam lithography to form structures that have both a high resolution and an excellent resistance to chemicals employed to remove the absorbent layer of heavy atoms in unprotected regions.

The abovementioned lithographic processes suffer from limitations that can become extremely constraining in the fabrication of sub-100 nm devices. These limitations include undesirable proximity effects in the photo resist and resolution limits imposed by the electron or electromagnetic beam or the size of the polymer molecules in the photo resist.

In yet another method, a small stylus such as an atomic force microscope (AFM) probe has been used to transfer a small amount of chemical to a surface to be patterned, thus leaving a very small feature on the surface. This method is limited to the chemicals used and the mechanics of the probes themselves.

Accordingly, there exists a need to provide a simple, convenient, and effective method of manufacturing nanoscale devices, such as nanofluidic devices.

### BRIEF SUMMARY OF THE INVENTION

The invention provides for a device comprising a substrate, a first material disposed on the substrate to form a first material layer, a second material disposed on the substrate to form a second material layer, and a nanochannel bounded by the substrate, the first material layer, and the second material layer.

The invention further provides a method of manufacturing a nanoscale device comprising the steps of (a) providing a substrate, (b) depositing a first material on the substrate to form a first material layer, (c) patterning the first material, (d) forming a third material layer on the first material layer, (e) depositing a second material on the substrate, the first material layer, the third material layer, or combinations thereof to form a modified substrate, (f) patterning the second material, (g) polishing the modified substrate to remove at least a portion of the first material layer, the second material layer, the third material layer, or combinations thereof, to create a planar modified substrate, and (h) removing the third material layer to form a nanoscale device comprising a nanochannel bounded by the substrate, the first material layer, and the second material layer.

### BRIEF DESCRIPTION OF THE DRAWINGS

FIG. 1 is a three-dimensional cross-sectional view of an embodiment of a nanoscale device in accordance with the invention.

FIG. 2 is a cross-sectional view of the nanoscale device of FIG. 1 further comprising an etch stopping layer.

FIG. 3 is a cross-sectional view of the nanoscale device of FIG. 1 following the deposition and patterning of a capping layer.

FIG. 4A is a cross-sectional view of a nanoscale device after a first material layer has been deposited and patterned on a substrate. FIG. 4B is a top view of the nanoscale device depicted in FIG. 4A.

FIG. 5A is a cross-sectional view of a nanoscale device after a third material layer has been deposited on a substrate. FIG. 5B is a top view of the nanoscale device depicted in FIG. 5A.

FIG. 6A is a cross-sectional view of the nanoscale device of FIG. 5A following the deposition of a second material layer to form a modified substrate. FIG. 6B is a top view of the nanoscale device depicted in FIG. 6A.

FIG. 7A is a cross-sectional view of nanoscale device of FIG. 6A following polishing of a modified substrate. FIG. 7B is a top view of the nanoscale device depicted in FIG. 7A.

FIG. 8A is a cross-sectional view of nanoscale device of FIG. 8A following the removal of the third material layer. FIG. 8B is a top view of the nanoscale device depicted in FIG. 8A.

FIG. 9 is a cross-sectional view of the nanoscale device of FIG. 6A further comprising an etch stopping layer.

### DETAILED DESCRIPTION OF THE INVENTION

The invention provides for a device comprising a substrate, a first material disposed on the substrate to form a first material layer, a second material disposed on the substrate to form a second material layer, and a nanochannel bounded by the substrate, the first material layer, and the second material layer.

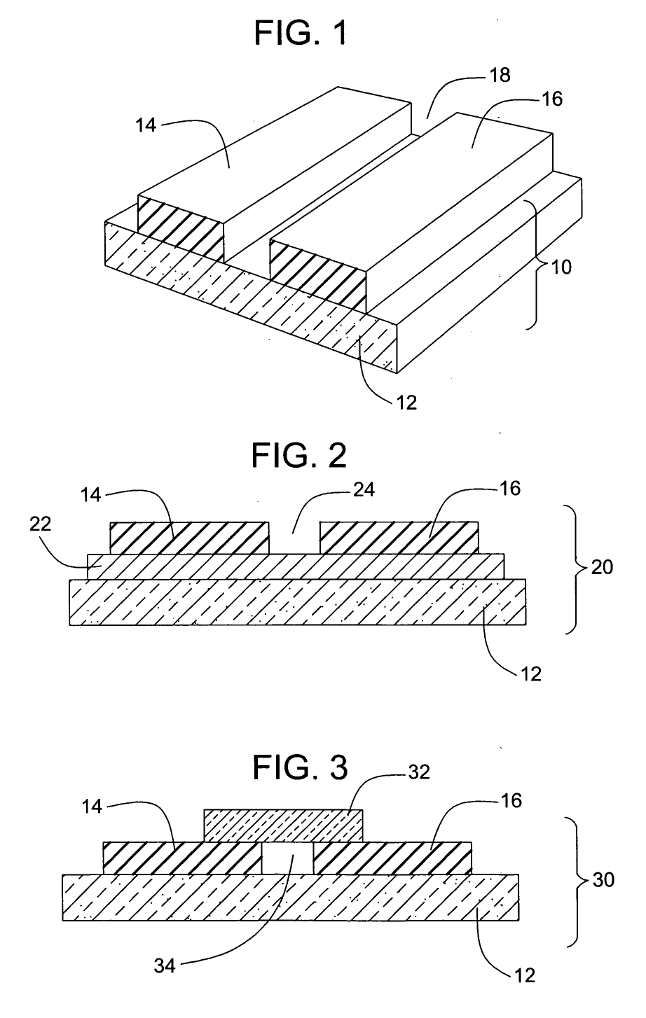

FIG. 1 is a cross-sectional view of one possible embodiment of a nanoscale device in accordance with the invention. The nanoscale device 10 may be formed on a substrate 12. Substrate 12 can be any suitable substrate. There are many suitable substrates well known in the art, such as, for example, silicon, quartz, silicon carbide, substrate silicon, epitaxial silicon, glass, boron carbide, diamond, silicon carbide, titanium nitride, and tungsten carbide.

Disposed on the substrate 12 is a first material layer 14 and a second material layer 16. The first material layer 14 can be made of any suitable material. Similarly, the second material layer 16 can be made of any suitable material. There are many suitable materials that can be the first material layer 14 or the second material layer 16, many of which are well known in the art, such as, for example, polysilicon. The first material layer 14 can be the same or different from the second material layer 16.

The nanoscale device 10 also contains a nanochannel 18. Nanochannel 18 is bounded by substrate 12, first material layer 14, and second material layer 16. Typically, nanochannel 18 has a width about 2 nm to about 2000 nm, about 2 nm to about 100 nm, about 1 nm to about 50 nm, about 1 nm to about 25 nm, or about 1 nm to about 15 nm. In accordance with the invention, the width of nanochannel 18 is a length of a smallest dimension of nanochannel 18 that is parallel to the surface of substrate 12.

FIG. 2 is a cross-sectional view of another possible embodiment of a nanoscale device in accordance with the invention. As can be seen in FIG. 2, the invention further provides for a nanoscale device 20 comprising a substrate 12, an etch stopping layer 22 disposed on the substrate 12, a first material layer 14 disposed on the etch stopping layer 22, a second material layer 16 disposed on the etch stopping layer 22, and a nanochannel 24 bounded by the etch stopping layer 22, the first material layer 14, and the second material layer 16. The nanochannel 24 typically has the same width as described for nanochannel 18 in FIG. 1.

The etch stopping layer 22 can be made of any suitable material. There are many suitable materials well known in the art, such as, for example, silicon nitride, alumina, and metal.

FIG. 3 is a cross-sectional view of a nanotube device in accordance with the invention. The nanotube device 30 comprises substrate 12. Disposed on substrate 12 is first material layer 14 and second material layer 16. The nanotube device 30 further comprises a capping material layer 32 disposed on the first material layer 14 and second material layer 16. The capping material layer 32 can be coextensive or not coextensive with the first material layer 14 and second material layer 16, and can overlap or not overlap the substrate 12. Nanotube 34 is bounded by substrate 12, first material layer 14, second material layer 16, and capping material layer 32. The capping material layer 32 can be any suitable capping material. There are many capping materials well known in the art, such as, for example, elastomers, polydimethylsiloxane, and glass. The nanotube 34 typically has the same width as described for nanochannel 18 in FIG. 1. In addition, the nanotube 34 has a height of about 2 nm to about 2000 nm, about 2 nm to about 100 nm, about 1 nm to about 50 nm, about 1 nm to about 25 nm, or about 1 nm to about 15 nm. In accordance with the invention, the height of nanotube 34 is the shortest distance from the surface of substrate 12 to the bottom of capping layer 32.

The nanotube device 30 optionally further comprises an etch stopping layer as disclosed in FIG. 2.

The invention further provides for a first method of manufacturing a nanoscale device comprising the steps of (a) providing a substrate, (b) depositing a first material on the substrate to form a first material layer, (c) patterning the first material, (d) forming a third material layer on the first material layer, (e) depositing a second material on the substrate, the first material layer, the third material layer, or combinations thereof to form a modified substrate, (f) patterning the second material, (g) polishing the modified substrate to remove at least a portion of the first material layer, the second material layer, the third material layer, or combinations thereof, to create a planar modified substrate, and (h) removing the third material layer to form a nanoscale device comprising a nanochannel bounded by the substrate, the first material layer, and the second material layer.

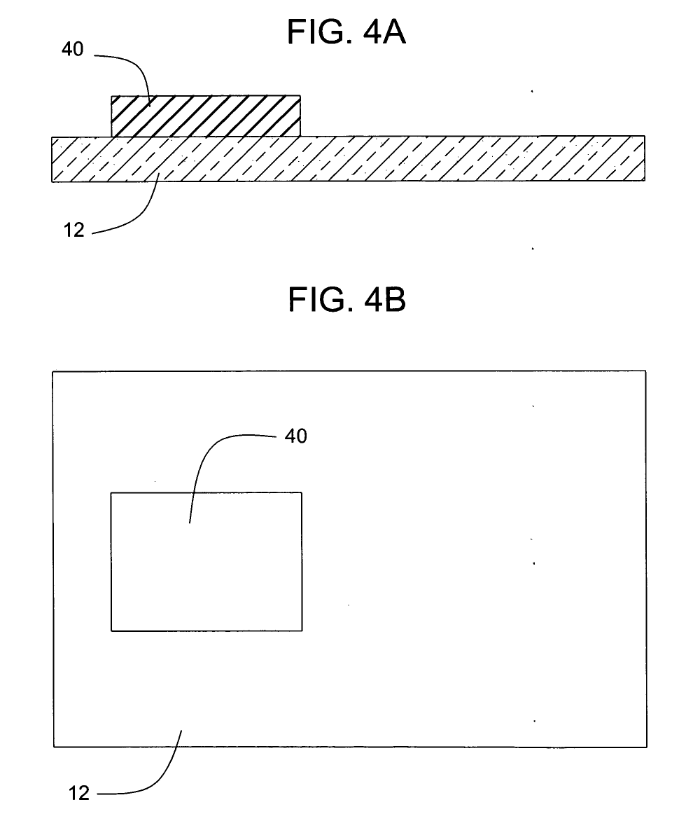

FIG. 4A is a cross-sectional view of one possible embodiment of the nanoscale device after manufacturing steps (a) and (b) in accordance with the invention. In the first step of manufacturing, the substrate 12 is provided onto which a first material is deposited onto substrate 12 to form first material layer 40. FIG. 4B is a top view of FIG. 4A.

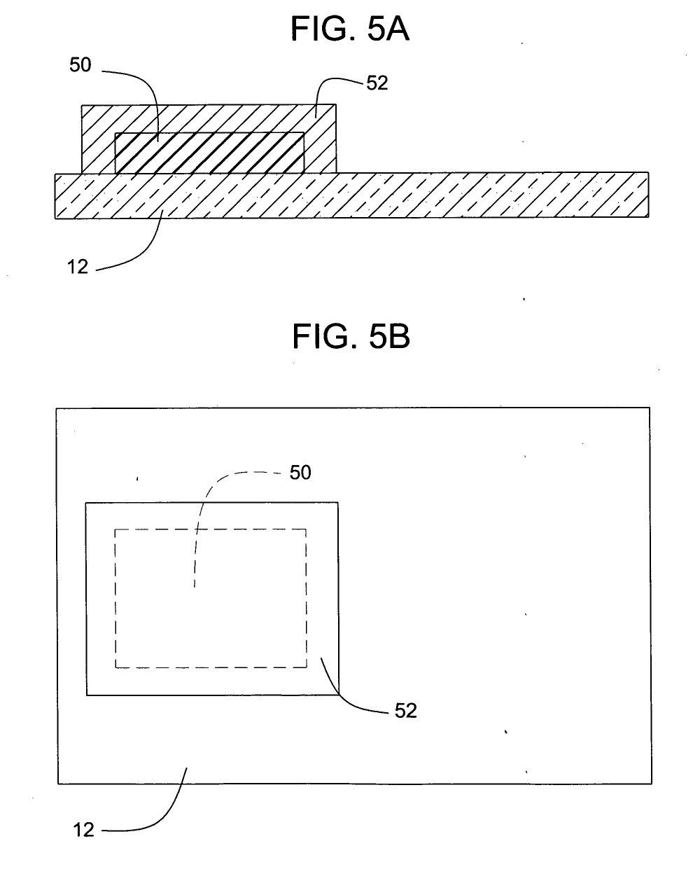

FIG. 5A is a cross-sectional view of one possible embodiment of the nanoscale device after manufacturing steps (c) and (d) in accordance with the invention. As seen in FIG. 5A, after the first material layer 40 is deposited onto the substrate 12, the first material layer 40 is patterned to form patterned first material layer 50. The first material layer 40 can be patterned by any suitable method. There are many methods of patterning the first material layer 40 that are well known in the art, such as, for example, e-beam lithography, ion beam lithography, and photolithography. Next, a third material layer 52 is deposited onto a portion of substrate 12 and patterned first material layer 50. Third material layer 52 can be coextensive or not coextensive with patterned first material layer 50. The third material layer 52 can be any suitable material. There are many suitable materials well known in the art, such as, for example, an oxide. FIG. 5B is a top view of FIG. 5A.

If the third material layer 60 comprises an oxide layer, the step of forming the oxide layer can comprise oxidizing the patterned first material layer 50 by any suitable method. There are many suitable methods well known in the art, such as, for example, steam oxidation, plasma enhanced chemical-vapor deposition, or dry oxidation. In the event that the patterned first material layer 50 is oxidized by steam oxidation, the steam oxidation can be performed at any suitable temperature, desirably at a temperature of about 500 to about 900 degrees Celsius, e.g., about 600 to about 800 degrees Celsius, about 650 to about 750 degrees Celsius, or about 675 to about 725 degrees Celsius. Furthermore, the steam oxidation can be performed for any suitable period of time, desirably for about 5 minutes or more, e.g., about 10 minutes or more, about 20 minutes or more, about 40 minutes or more, about 60 minutes or more, or about 75 minutes or more. Typically, the steam oxidation is performed for about 5 minutes to about 60 minutes, e.g., about 10 minutes to about 40 minutes, about 15 minutes to about 30 minutes, or about 20 minutes to about 30 minutes.

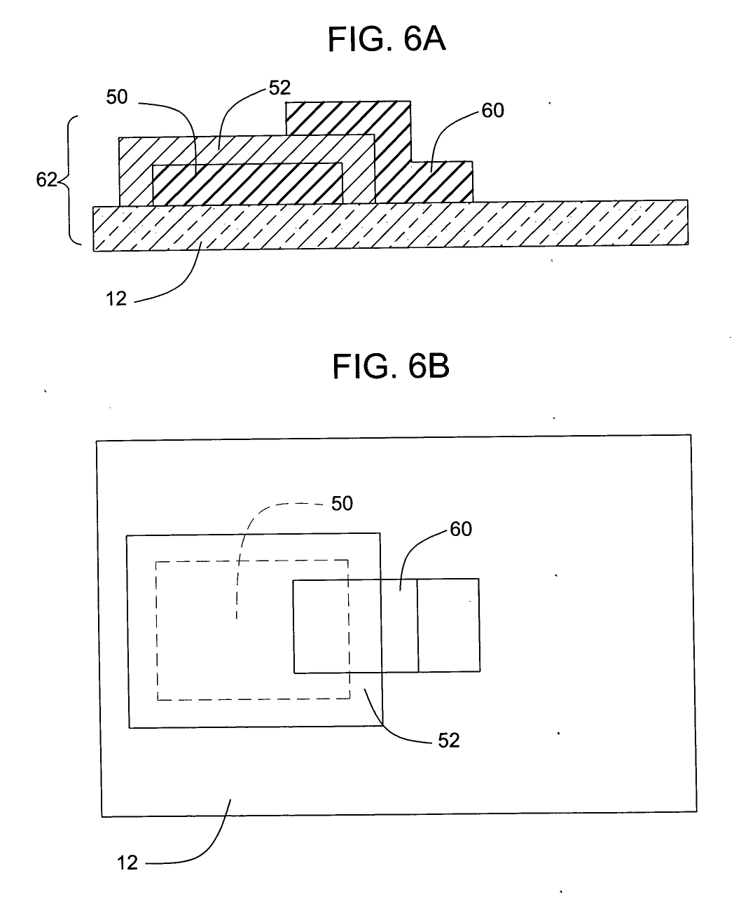

FIG. 6A is a cross-sectional view of one possible embodiment of the nanoscale device after manufacturing step (e) in accordance with the invention. As seen in FIG. 6A, a second material layer 60 has been deposited onto a portion of substrate 12, patterned first material layer 50, and third material layer 52 to form a modified substrate 62. Second material layer 60 also can be deposited onto combinations of substrate 12; patterned first material layer 50, or third material layer 52. Moreover, second material layer 60 can be deposited adjacent to third material layer 52 and exclusively on top of substrate 12. FIG. 6B is a top view of FIG. 6A.

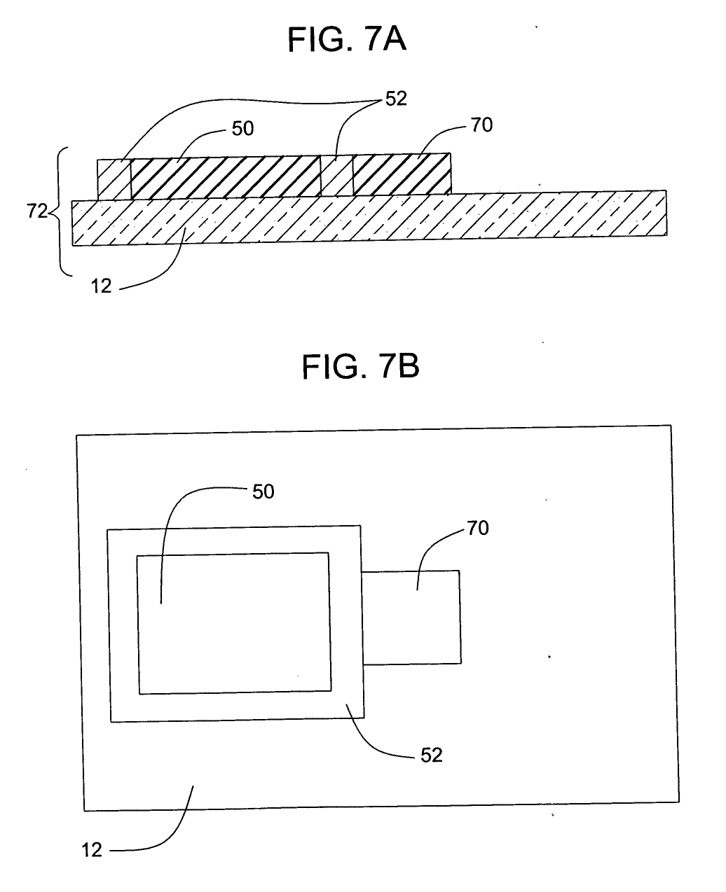

FIG. 7A is a cross-sectional view of one possible embodiment of the nanoscale device after manufacturing steps (f) and (g) in accordance with the invention. After the second material layer 60 is deposited onto the substrate 12, the second material layer 60 is patterned to form patterned second material layer 70. The second material layer 60 can be patterned by any suitable method. There are many methods of patterning the second material layer 60 that are well known in the art, such as, for example, e-beam lithography, ion beam lithography, or photolithography.

After second material layer 60 has been patterned, modified substrate 62 is polished to remove at least a portion of patterned first material layer 50, patterned second material layer 70, and third material layer 52 to create a planar modified substrate 72. The modified substrate 62 can be polished by any suitable method. There are many methods of polishing modified substrate 62 that are well known in the art, such as, for example, chemical-mechanical polishing, mechanical polishing, electro-mechanical polishing, or combinations thereof. FIG. 7B is a top view of FIG. 7A.

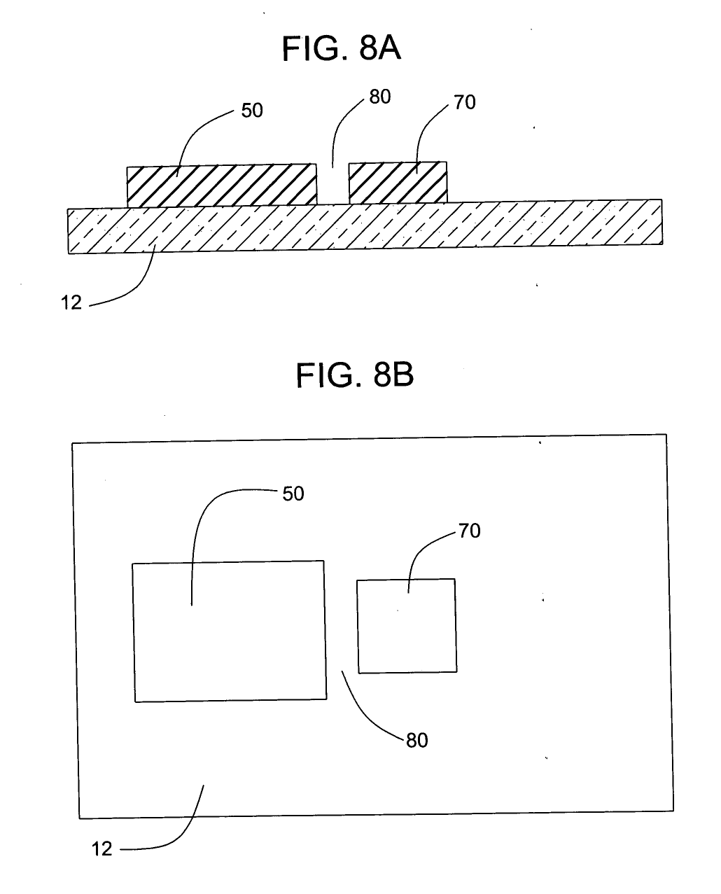

FIG. 8A is a cross-sectional view of one possible embodiment of the nanoscale device after manufacturing step (h) in accordance with the invention. As seen in FIG. 8A, the third material layer 52 has been removed from the planar modified substrate 72 of FIG. 7A. As a result, nanochannel 80 is formed, which is bounded by substrate 12, patterned first material layer 50, and patterned second material layer 70. The third material layer 52 can be removed by any suitable method. There are many suitable methods well known in the art, such as, for example, the employment of hydrofluoric acid, buffered hydrofluoric acid, or plasma etching. FIG. 8B is a top view of FIG. 8A and depicts nanochannel 80.

The invention also provides a second method of manufacturing a nanoscale device comprising the steps of (a) providing a substrate, (b) depositing an etch stopping material on the substrate to form an etch stopping layer, (c) depositing a first material on the etch stopping layer to form a first material layer, (d) patterning the first material, (e) forming a third material layer on the first material layer, (f) depositing a second material on the etch stopping layer, the first material layer, the third material layer, or combinations thereof to form a modified substrate, (g) patterning the second material, (h) polishing the modified substrate to remove at least a portion of the etch stopping layer, the first material layer, the second material layer, the third material layer, or combinations thereof, to create a planar modified substrate, and (i) removing the third material layer to form a nanoscale device comprising a nanochannel bounded by the etch stopping layer, the first material layer, and the second material layer. The discussion herein of aspects of the first method is applicable to the similar aspects of this second method.

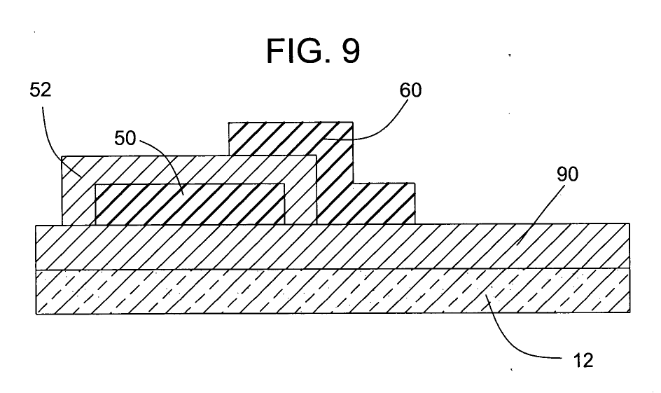

FIG. 9 is a cross-sectional view of one possible embodiment of the nanoscale device after manufacturing steps (a) to (e) in accordance with the second method of manufacturing a nanoscale device. As seen in FIG. 9, on top of substrate 12 is deposited etch stopping layer 90. Etch stopping layer 90 can be coextensive or not coextensive with substrate 12. On top of etch stopping layer 90 is patterned first material layer 50, third material layer 52, and second material layer 60.

In addition, first material layer 50 can be deposited coextensively or not coextensively with etch stopping layer 90. If etch stopping layer 90 is not deposited coextensively on substrate 12, then first material layer 50 can be coextensive or not coextensive with the exposed surfaces of substrate 12. Second material layer 60 can be deposited exclusively or not exclusively on etch stopping layer 90.

Manufacturing steps (f) to (i) in accordance with the second method of manufacturing a nanoscale device are similar to manufacturing steps (e) to (h) of the first method of manufacturing a nanoscale device as discussed herein.

Those skilled in the art will understand that the nanochannel devices and nanotube devices described have many applications, for example, in biotechnology, chemical analysis, nanoscale reactions, and the like.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A device comprising:
(a) a substrate,
(b) a first material disposed on the substrate to form a first material layer,
(c) a second material disposed on the substrate to form a second material layer, and
(d) a nanochannel bounded by the substrate, the first material layer, and the second material layer.

2. The device of claim 1, wherein the substrate comprises silicon, quartz, silicon carbide, substrate silicon, epitaxial silicon, or glass.

3. The device of claim 1, wherein the device further comprises a capping material disposed on the first and second material layers to form a capping material layer, such that the nanochannel is further bounded by the capping material layer, thereby forming a nanotube.

4. The device of claim 3, wherein the capping material comprises an elastomer, a polydimethylsiloxane, or glass.

5. The device of claim 1, wherein the nanochannel has a width of about 2 nm to about 2000 nm.

6. The device of claim 5, wherein the nanochannel has a width of about 2 nm to about 100 nm.

7. The device of claim 1, wherein the first and second materials comprise polysilicon.

8. A device comprising:
(a) a substrate,
(b) an etch stopping material disposed on the substrate to form an etch stopping layer,
(c) a first material disposed on the etch stopping layer to form a first material layer,
(d) a second material disposed on the etch stopping layer to form a second material layer, and
(e) a nanochannel bounded by the etch stopping layer, the first material layer, and the second material layer.

9. The device of claim 8, wherein the etch stopping material comprises silicon nitride, alumina, or a metal.

10. A method of manufacturing a nanoscale device comprising the steps of:
(a) providing a substrate,
(b) depositing a first material on the substrate to form a first material layer,
(c) patterning the first material,
(d) forming a third material layer on the first material layer,
(e) depositing a second material on the substrate, the first material layer, the third material layer, or combinations thereof to form a modified substrate,
(f) patterning the second material,
(g) polishing the modified substrate to remove at least a portion of the first material layer, the second material layer, the third material layer, or combinations thereof, to create a planar modified substrate, and
(h) removing the third material layer to form a nanoscale device comprising a nanochannel bounded by the substrate, the first material layer, and the second material layer.

11. The method of claim 10, wherein the substrate comprises silicon, quartz, silicon carbide, or glass.

12. The method of claim 10, further comprising disposing a capping material on the first and second material layers to form a capping material layer, such that the nanochannel is further bounded by the capping material layer, thereby forming a nanotube.

13. The method of claim 12, wherein the capping material comprises an elastomer, a polydimethylsiloxane, or glass.

14. The method of claim 12, wherein the capping material layer is coextensive with a surface of the planar modified substrate.

15. The method of claim 12, wherein the capping material layer is not coextensive with a surface of the planar modified substrate.

16. The method of claim 10, wherein the third material layer is an oxide layer.

17. The method of claim 16, wherein the step of forming the oxide layer comprises oxidizing the first material by steam oxidation, plasma enhanced chemical-vapor deposition, or dry oxidation.

18. The method of claim 17, wherein the oxidizing of the first material is performed by steam oxidation.

19. The method of claim 18, wherein the steam oxidation is performed at about 500 to about 900 degrees Celsius.

20. The method of claim 19, wherein the steam oxidation is preformed at about 600 to about 800 degrees Celsius.

21. The method of claim 20, wherein the steam oxidation is preformed at about 650 to about 750 degrees Celsius.

22. The method of claim 18, wherein the steam oxidation is performed for about 5 minutes to about 60 minutes.

23. The method of claim 22, wherein the steam oxidation is performed for about 10 minutes to about 40 minutes.

24. The method of claim 23, wherein the steam oxidation is performed for about 15 minutes to about 30 minutes.

25. The method of claim 10, wherein the step of depositing the second material is performed such that a portion of the second material is deposited on a portion of the first material layer.

26. The method of claim 10, wherein the step of removing the third material layer comprises the use of hydrofluoric acid, buffered hydrofluoric acid, or plasma etching.

27. The method of claim 10, wherein the step of polishing comprises chemical-mechanical polishing, mechanical polishing, electro-mechanical polishing, or combinations thereof.

28. The method of claim 10, wherein the step of patterning the first material comprises e-beam lithography, ion beam lithography, or photolithography.

29. The method of claim 10, wherein the step of patterning the second material comprises e-beam lithography, ion beam lithography, or photolithography.

30. A method of manufacturing a nanoscale device comprising the steps of:
(a) providing a substrate,
(b) depositing an etch stopping material on the substrate to form an etch stopping layer,
(c) depositing a first material on the etch stopping layer to form a first material layer,
(d) patterning the first material,
(e) forming a third material layer on the first material layer,
(f) depositing a second material on the etch stopping layer, the first material layer, the third material layer, or combinations thereof to form a modified substrate,
(g) patterning the second material,
(h) polishing the modified substrate to remove at least a portion of the etch stopping layer, the first material layer, the second material layer, the third material layer, or combinations thereof, to create a planar modified substrate, and
(i) removing the third material layer to form a nanoscale device comprising a nanochannel bounded by the etch stopping layer, the first material layer, and the second material layer.

31. The method of claim 30, wherein the step of depositing the second material is performed such that the second material layer is deposited exclusively on the etch stopping layer.

32. The method of claim 30, wherein the etch stopping material comprises silicon nitride, alumina, a metal, or combinations thereof.

33. The method of claim 30, wherein the first material layer is coextensive with the etch stopping layer.

34. The method of claim 30, wherein the first material layer is not coextensive with the etch stopping layer.

35. The method of claim 30, wherein the etch stopping layer is coextensive with the substrate.

36. The method of claim 30, wherein the etch stopping layer is not coextensive with the substrate.
